(19) United States
(12) Patent Application Publication
(10) Pub. No.: US 2024/0322775 A1
(43) Pub. Date: Sep. 26, 2024

(54) THREE-DIMENSIONAL POWER COMBINERS

(71) Applicant: Intel Corporation, Santa Clara, CA (US)

(72) Inventors: Telesphor Kamgaing, Chandler, AZ (US); Peter Baumgartner, Munich (DE); Steven Callender, Denver, CO (US); Richard Geiger, Munich (DE); Harald Gossner, Riemerling (DE); Jonathan Jensen, Portland, OR (US)

(73) Assignee: Intel Corporation, Santa Clara, CA (US)

(21) Appl. No.: 18/187,001

(22) Filed: Mar. 21, 2023

(51) Int. Cl. H03F 3/60; H01L 23/66; H03F 3/195; H03F 3/24

(52) U.S. Cl. CPC H03F 3/602; H01L 23/66; H03F 3/195; H03F 3/245; H01L 2223/6677; H03F 2200/294; H03F 2200/451

(57) ABSTRACT

Disclosed herein are electronic assemblies, integrated circuit (IC) packages, and communication devices implementing three-dimensional power combiners. An electronic assembly may include a first die, comprising a first transmission line, and a second die, comprising a second transmission line. Each die includes a first face and an opposing second face, and the second die is stacked above the first die so that the first face of the second die is coupled to the second face of the first die. The electronic assembly further includes a first conductive pathway between one end of the first transmission line and a first connection point at the first face of the first die, a second conductive pathway between one end of the second transmission line and a second connection point at the first face of the first die, and a third conductive pathway between the other ends of the first and second transmission lines.

### BACKGROUND

A power combiner is a device that may be configured to combine the power from multiple sources into a single output. To that end, a power combiner includes two or more branches, each branch including a transmission line for transmitting signals to be combined, where transmission lines of different branches are coupled to respective signal sources at one end and coupled together to a single output at the other end. Such a device may also be operated in reverse, where the ends of the transmission lines of different branches that are coupled together are coupled to a single input and the other ends of the transmission lines of different branches are coupled to respective outputs. In this manner, the device may also be used to divide an incoming signal into multiple paths and may be referred to as a “power divider.” Because a single device may be configured to operate either as a power combiner or a power divider, depending on the configuration of the inputs and outputs of the device, the term “power combiner” may be used to refer to both power combiners and power dividers.

Power combiners may be used in wireless communication devices, such as handheld computing devices and wireless access points. A power combiner configured to combine multiple input signals into a single output may be used in a transmit (TX) path of a wireless communication device to combine outputs of multiple power amplifiers (PAs) into a single output that may be provided to an antenna. A power combiner configured to divide a single input signal into multiple outputs may be used in a receive (RX) path of a wireless communication device to divide a signal generated by an antenna into multiple outputs for further processing, e.g., for further processing by respective low-noise amplifiers (LNAs) associated with different branches of a power combiner.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of a three-dimensional power combiner arrangement, in accordance with various embodiments.

FIGS. 2 and 3 are side, cross-sectional views of example electronic assemblies with three-dimensional power combiner arrangements, in accordance with various embodiments.

FIGS. 4-7 are side, cross-sectional views of example integrated circuit (IC) packages that may include three-dimensional power combiner arrangements, in accordance with various embodiments.

FIG. 8 is a top-down view of an example IC package that may include three-dimensional power combiner arrangements, in accordance with various embodiments.

FIGS. 9-11 are side, cross-sectional views of example antenna substrates, in accordance with various embodiments.

FIGS. 12 and 13 are side, cross-sectional views of example antenna units, in accordance with various embodiments.

FIG. 14 is a perspective view of a handheld communication device including an IC package with one or more power combiner arrangements, in accordance with various embodiments.

FIG. 15 is a perspective view of a laptop communication device including multiple IC packages with one or more power combiner arrangements, in accordance with various embodiments.

FIG. 16 is a top view of a wafer and dies that may be included in a three-dimensional power combiner arrangement in accordance with any of the embodiments disclosed herein.

FIG. 17 is a side, cross-sectional view of an IC device that may include one or more three-dimensional power combiner arrangements in accordance with any of the embodiments disclosed herein.

FIG. 18 is a side, cross-sectional view of an IC device assembly that may include one or more three-dimensional power combiner arrangements in accordance with any of the embodiments disclosed herein.

FIG. 19 is a block diagram of an example communication device that may include one or more three-dimensional power combiner arrangements in accordance with any of the embodiments disclosed herein.

FIG. 20 is a block diagram of an example radio frequency (RF) device that may include one or more three-dimensional power combiner arrangements in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC packages with 3D power combiners, proposed herein, it might be useful to first understand phenomena that may come into play in some systems where power combiners may be used. The following foundational information may be viewed as a basis from which the present disclosure may be properly explained. Such information is offered for purposes of explanation only and, accordingly, should not be construed in any way to limit the broad scope of the present disclosure and its potential applications.

One class of systems where power combiners may be used are wireless communication systems that transmit and receive signals in the form of electromagnetic waves in the RF range of approximately 3 kiloHertz (kHz) to 300 gigaHertz (GHz) and beyond. In context of a wireless communication system, an antenna is a device that serves as the interface between electromagnetic waves propagating wirelessly through space and electric currents moving in metal conductors used with a transmitter or a receiver of a wireless communication device. During transmission, a transmitter supplies an electric current to the antenna's terminals, and the antenna radiates the energy from the current as electromagnetic waves. During reception, an antenna intercepts some of the power of an electromagnetic wave in order to produce an electric current at its terminals, which current is subsequently applied to a receiver to be amplified.

Antennas are essential components of all wireless communication devices. An antenna with a single antenna unit will typically broadcast a radiation pattern that radiates in all directions in a spherical wavefront. Phased arrays generally refer to a collection of antenna units that are used to focus electromagnetic energy in a particular direction, thereby creating a main beam. Phased arrays offer numerous advantages over single antenna systems, such as high gain, ability to perform directional steering, and simultaneous communication, and, therefore, are particularly important for modern wireless communication systems.

As the frequency of operation of wireless communication devices increased into the millimeter wave, sub-Terahertz (THz), and THz regions, the output power of semiconductor devices used in the transceivers decreases substantially. In order to increase the overall strength of the transmitted signal, an on-chip power combiner may be used between the last amplification stage and an antenna unit or an antenna port. Even though the wavelength is small at such frequencies, a multi-branch power combiner occupies a significant area, therefore, leading to die size and cost increase. This problem is further exacerbated for wireless communication devices employing phased arrays, where a respective power combiner may need to be provided for each of the antenna units.

Disclosed herein are electronic assemblies, IC packages, and communication devices that may enable wireless communications such as millimeter wave and THz communications in a compact form factor by implementing three-dimensional power combiners. Such assemblies, packages, and devices may include a plurality of dies stacked above one another, where individual dies include respective transmission lines that may be configured to serve as different branches of a power combiner. By stacking the dies above one another different branches of a power combiner may be provided in different planes, thus realizing a three-dimensional power combiner. The three-dimensional integration may enable compactness and form factor reduction. In some embodiments, adjacent dies of the stack may be coupled to one another using direct bonding interconnects (also referred to as “hybrid bonding interconnects”), which may advantageously lead to reduced impedance discontinuity at high frequencies. In some embodiments, the overall utilization of dies may be improved by re-orienting the circuits on the floor plan of the dies.

As an example, an electronic assembly according to some embodiments of the present disclosure may include a first die, comprising a first transmission line, and a second die, comprising a second transmission line. Each of the dies includes a first face and an opposing second face, and each of the transmission lines has a first end and an opposing second end. The second die may be stacked above the first die so that the first face of the second die is coupled to the second face of the first die. The electronic assembly may further include a first conductive pathway between the first end of the first transmission line and a first connection point at the first face of the first die, a second conductive pathway between the first end of the second transmission line and a second connection point at the first face of the first die, and a third conductive pathway between the second end of the first transmission line and the second end of the second transmission line. The first and second transmission lines of such an electronic assembly may form different branches of a power combiner. Because the first and second transmission lines are provided in dies stacked above one another, such a power combiner may be referred to as a “three-dimensional power combiner,” to differentiate it from conventional power combiners where different branches are provided in a single plane (e.g., on a single die).

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Any of the features discussed with reference to any of accompanying drawings herein may be combined with any other features to form a power combiner arrangement 100, an electronic assembly 130, an IC package 140, or a communication device, as appropriate. A number of elements of the drawings are shared with others of the drawings; for ease of discussion, a description of these elements is not repeated, and these elements may take the form of any of the embodiments disclosed herein. Also for convenience, the phrase “dies 104” may be used to refer to the collection of dies 104-1, 104-2, and so on, the phrase “transmission lines 106” may be used to refer to the collection of transmission lines 106-1, 106-2, and so on, etc. To not clutter the drawings, if multiple instances of certain elements are illustrated, only some of the elements may be labeled with a reference sign. The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electro microscopy (SEM) images or transmission electro microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of three-dimensional power combiners as described herein.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “IC package” are synonymous, as are the terms “die” and “IC die.” Furthermore, the terms “chip,” “chiplet,” “die,” and “IC die” may be used interchangeably herein.

Although certain elements may be referred to in the singular herein, such elements may include multiple sub-elements. For example, “a dielectric material” may include one or more dielectric materials. The terms “oxide,” “carbide,” “nitride,” etc. refer to compounds containing, respectively, oxygen, carbon, nitrogen, etc. The term “high-k dielectric” refers to a material having a higher dielectric constant than silicon oxide, while the term “low-k dielectric” refers to a material having a lower dielectric constant than silicon oxide. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. With reference to optical signals and/or devices, components and elements that operate on or using optical signals, the term “conducting” can also mean “optically conducting.” The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components. The term “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., printed circuit board (PCB) or Printed Wiring Boards (PWB)), glass, ceramic, silicon, silicon carbide, etc. In addition, as used herein, a package substrate may refer to a substrate that includes buildup layers (e.g., ABF layers). In some embodiments, a package substrate may be a PCB or a multilayer package substrate that includes a core including glass, e.g., a core including a glass layer, where the glass layer may be bulk glass or a solid volume of glass, as opposed to, e.g., glass fiber reinforced polymers (i.e., in some embodiments, the glass layer does not include any glass fiber reinforced polymers).

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides (e.g., structures that guide and confine light waves), including optical fiber, optical splitters, optical combiners, optical couplers, and optical vias.

The term “metallization stack” may be used to refer to a stack of one or more interconnects for providing connectivity to different circuit components of an IC die/chip and/or a package substrate. The term “conductive trace” may be used to describe an electrically conductive element isolated by an insulating material. Within IC dies, such insulating material comprises interlayer low-k dielectric that is provided within the IC die. Within package substrates, and PCBs such insulating material may comprise organic materials such as Ajinomoto Buildup Film (ABF), polyimides, or epoxy resin. Such conductive lines are typically arranged in several levels, or several layers, of metallization stacks. The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

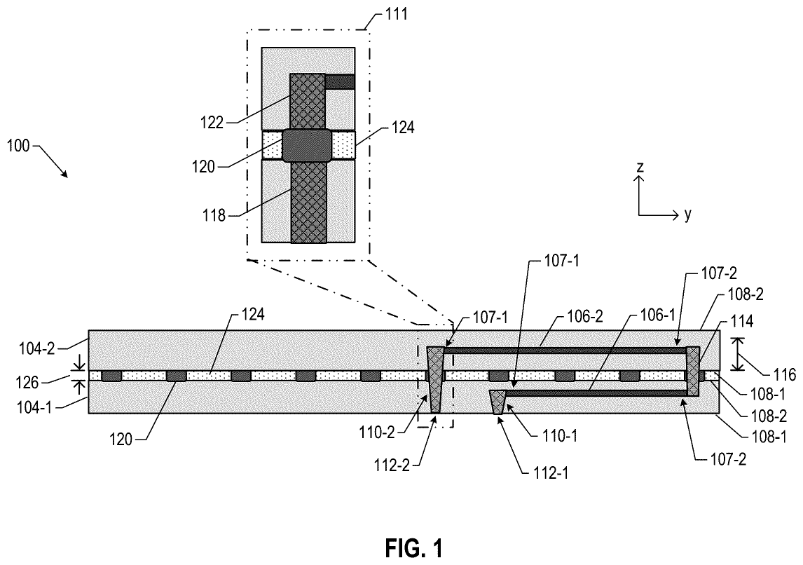

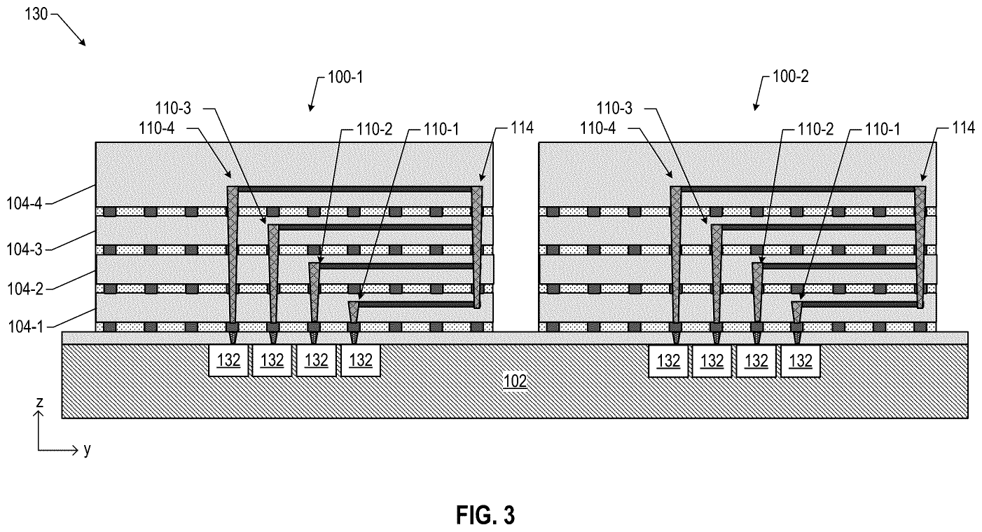

FIG. 1 is a side, cross-sectional view of a three-dimensional power combiner arrangement 100, in accordance with various embodiments. The power combiner arrangement 100 may include a plurality of dies 104, shown as a first die 104-1 and a second die 104-2. Although two dies 104 are illustrated in FIG. 1, a power combiner arrangement 100 may include more than two IC dies 104 stacked above one another (e.g., as discussed below with reference to FIG. 3). Each of the dies 104 may include a transmission line 106, shown as a first transmission line 106-1 in the first die 104-1 and a second transmission line 106-2 in the second die 104-2. Although one transmission line 106 is illustrated in each die 104, a power combiner arrangement 100 may include two or more transmission lines 106 in at least some of the dies 104. In some embodiments, the transmission lines 106 may be vertically aligned (e.g., projections of the first and second transmission lines 106-1, 106-2, onto a plane parallel to the first or the second face of the first die 104-1 may be overlapping). However, in other embodiments, the transmission lines do not have to be vertically aligned and may, instead, be offset with respect to one another (e.g., projections of the first and second transmission lines 106-1, 106-2, onto a plane parallel to the first or the second face of the first die 104-1 may be non-overlapping). Transmission lines 106 may be any suitable RF transmission structures (e.g., antenna feed structures, such as striplines, microstrip transmission lines, or coplanar waveguides). The power combiner arrangement 100 may further include conductive pathways 110 and 114, e.g., provided by conductive vias and lines through one or more dielectric materials. As used herein, the term “conductive” means “electrically conductive,” and the term “conductive pathway between A and B” refers to any electrically conductive pathway provided by electrically conductive vias and/or lines through one or more dielectric materials to electrically connect (e.g., directly electrically connect) A and B.

As shown in FIG. 1, each of the dies 104 may include a first face 108-1 and an opposing second face 108-2. The dies 104-1 and 104-2 may be coupled to one another so that the first face 108-1 of the die 104-2 is coupled to the second face 108-1 of the die 104-1. In some embodiments, each of the dies 104 of the power combiner arrangement 100 may be a relatively thin die, e.g., with a thickness 116 being below about 40 microns, e.g., between about 2 microns and 40 microns, between about 5 microns and 30 microns, or between about 10 microns and 30 microns.

Each of the transmission lines 106 may include a first end 107-1 and an opposing second end 107-2. A conductive pathway 110-1 may be between (i.e., electrically connecting, e.g., directly connecting) the first end 107-1 of the first transmission line 106-1 and a first connection point 112-2 at the first face 108-1 of the first die 104-1. A conductive pathway 110-2 may be between the first end 107-1 of the second transmission line 106-2 and a second connection point 112-2 at the first face 108-1 of the first die 104-1. More generally, if more than two dies 104 with transmission lines 106 are included in the power combiner arrangement 100 (e.g., as discussed below with reference to FIG. 3), conductive pathways 110 may be provided in a one-to-one correspondence for each of the transmission lines 106 of the power combiner arrangement 100 (i.e., a designated conductive pathway 110 is provided for each of the transmission lines 106) to couple the first ends 107-1 of different transmission lines 106 to different connection points at the first face 108-1 of the bottom die (e.g., the first die 104-1 for the scenarios illustrated in the present drawings). A conductive pathway 114 may be between the second end 107-2 of the first transmission line 106-1 and the second end 107-2 of the second transmission line 106-2, thus coupling these two transmission lines together. More generally, if more than two dies 104 with transmission lines 106 are included in the power combiner arrangement 100, conductive pathway 114 may couple the second ends 107-2 of different transmission lines 106 together. In this manner, multiple transmission lines 106 of the dies 104 stacked above one another provide different branches of a three-dimensional power combiner. Together, transmission lines 106 and conductive pathways 110, 114 provide a three-dimensional power combiner and, therefore, may enable one or more antenna units (not shown in FIG. 1) to transmit and receive electromagnetic waves under the control of circuitry included in (not shown in FIG. 1), or associated with, the power combiner arrangement 100. For example, when the power combiner arrangement 100 is used to combine multiple input signals into a single output, the multiple input signals for the power combiner arrangement 100 may be provided to different connections points 112 of the die 104-1 (e.g., different connection points 112 may be coupled to different PAs of an RF transceiver), while the single output signal of the power combiner arrangement 100 may be provided at a connection point coupled (e.g., directly connected) to the conductive pathway 114 (e.g., such a connection point may be coupled to an antenna or an antenna port of an RF transceiver). In another example, when the power combiner arrangement 100 is used to divide a single input signal into multiple outputs, the single input signal of the power combiner arrangement 100 may be provided to a connection point coupled (e.g., directly connected) to the conductive pathway 114 (e.g., such a connection point may be coupled to an antenna or an antenna port of an RF transceiver), while the multiple output signals from the power combiner arrangement 100 may be provided at different connections points 112 of the die 104-1 (e.g., different connection points 112 may be coupled to different LNAs of an RF transceiver).

FIG. 1 does not illustrate routing of the conductive pathway 114 to either the bottom of the power combiner arrangement 100 (e.g., to a connection point at the first face 108-1 of the first die 104-1) or the top of the power combiner arrangement 100 (e.g., to a connection point at the second face 108-2 of the second die 104-2) because either one of these connections is possible and is within the scope of the present disclosure. Furthermore, FIG. 1 and subsequent drawings of the power combiner arrangement 100 do not illustrate details how each of the conductive pathways 110, 114 are implemented because any of these conductive pathways may include any suitable combination of conductive vias and/or lines to provide electrical connectivity as described above. One example implementation is shown in an inset 111 shown in FIG. 1 for the conductive pathway 110-2, although other implementations are possible and within the scope of the present disclosure. As shown in the inset 111, the conductive pathway 110-2 may include a conductive via 118 extending through the first die 104-1 (i.e., extending between the first and second faces 108-1 and 108-2 of the first die 104-1), a direct bonding interconnect 120 between the first die 104-1 and the second die 104-2, and a conductive via 122 in the second die 104-2. The conductive via 118 may be a conductive pathway between a portion of the direct bonding interconnect 120 at the second face 108-2 of the first die 104-1 and the second connection point 112-2 at the first face 108-1 of the first die 104-1. The conductive via 122 may be a conductive pathway between the first end 107-1 of the second transmission line 106-2 and a portion of the direct bonding interconnect 120 at the first face 108-1 of the second die 104-2. Although not specifically shown in the present drawings, the example implementation shown in the inset 111 can be easily extended to other conductive pathways 110, 114 described herein. For the bottom die of the stack of the power combiner arrangement 100, a conductive via may be used between the first end 107-1 of the first transmission line 106-1 and the first connection point 112-1 at the first face 108-1 of the first die 104-1.

The direct bonding interconnect 120 shown in the inset 111 may be one of a plurality of direct bonding interconnects 120 coupling the first die 104-1 and the second die 104-2, with an insulator material 124 also being present between the first die 104-1 and the second die 104-2 and surrounding the direct bonding interconnects 120. Coupling various dies 104 stacked above one another using direct bonding interconnects 120 may advantageously allow reducing impedance discontinuity in the power combiner arrangement 100. Furthermore, direct bonding interconnects 120 may allow decreasing the distance between adjacent dies 104 stacked above one another, compared to, e.g., solder-based interconnects. For example, in some embodiments, the first and second dies 104-1, 104-2 may be separated by distance 126 that may be below about 10 microns, e.g., below about 5 microns or below about 2 microns, e.g., between about 0.5 microns and 2 microns.

As used herein, “direct bonding” (also sometimes referred to as “hybrid bonding”) refers to bonding of two dies 104 without using solder-based interconnects. In some embodiments, bonding of the opposite faces of a pair of IC dies 104 may be performed using insulator-insulator bonding, e.g., as oxide-oxide bonding, where an insulator material of one die 104 is bonded to an insulator material of the another die 104, resulting in the insulator material 124 being present at a direct bonding interface between the dies 104. To that end, in some embodiments, an insulator material may be applied to the one or both faces of the first and second dies 104 that should be bonded and then the dies 104 are pressed together, possibly while applying a suitable pressure and heating up the assembly to a suitable temperature (e.g., to moderately high temperatures, e.g., between about 50 and 130 degrees Celsius) for a duration of time. In some embodiments, the insulator material 124 may include an adhesive material that ensures attachment of the first and second dies 104 to one another. In some embodiments, the insulator material 124 may include an etch-stop material. In some embodiments, the insulator material 124 may be both an etch-stop material and have suitable adhesive properties to ensure attachment of the first and second dies 104 to one another. In some embodiments, the insulator material 124 may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the direct bonding where different dies 104 may be manufactured by different manufacturers or using different fabrication processes. Using an etch-stop material at the interface (i.e., the interface between the first and second dies 104) that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the first and second dies 104 together. In addition, an etch-stop material at the interface between the first and second dies 104 that includes include silicon, nitrogen, and carbon, where the atomic percentage of any of these materials may be at least 1%, may be advantageous in terms of improving etch selectivity of this material with respect to etch-stop materials that may be used in different of the first and second dies 104. In some embodiments, no deliberately added adhesive or bonding material may be used to bond the first and second dies 104, but there will still be a direct bonding interface in the form of the insulator material 124 resulting from the bonding of the first and second dies 104 to one another. Such a direct bonding interface may be recognizable as a seam or a thin layer in the electronic assembly, using, e.g., selective area diffraction (SED), even when the specific materials of the insulators of the first and second dies 104 that are bonded together may be the same, in which case the direct bonding interface would still be noticeable as a seam or a thin layer in what otherwise appears as a bulk insulator (e.g., bulk oxide) layer.

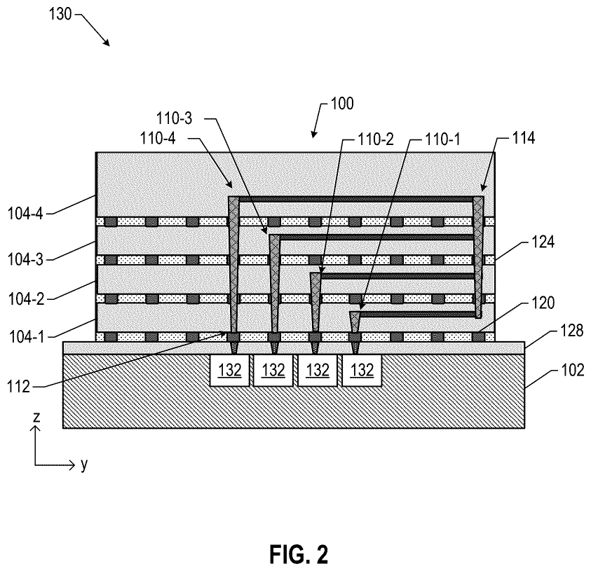

FIG. 2 is a side, cross-sectional view of an electronic assembly 130 with a three-dimensional power combiner arrangement 100, in accordance with various embodiments. The power combiner arrangement 100 shown in FIG. 2 is substantially as that shown in FIG. 1, except that it illustrates an example where four dies 104 may be used, each with a respective transmission line 106, to provide four branches of a power combiner. Correspondingly, the power combiner arrangement 100 shown in FIG. 2 includes four conductive pathways 110 coupled to respective connection points 112 at the first face 108-1 of the bottom die 104-1. FIG. 2 further illustrates that the three-dimensional power combiner arrangement 100 may be coupled to a die 102 with circuits 132 in such a way that different connection points 112 are coupled to respective circuits 132. To that end, the die 102 may include an insulator layer 128 and the bottom die of the three-dimensional power combiner arrangement 100 (i.e., the die 104-1) may be coupled to the insulator layer 128 of the die 102 using direct bonding interconnects 120.

The circuits 132 may include any suitable circuitry for controlling how the electromagnetic waves are transmitted and received. In some embodiments, any of the circuits 132 may include a termination resistor that is electrically coupled to two branches of the power combiner. In some embodiments, if the power combiner arrangement 100 is used to combine multiple input signals into a single output, then the circuits 132 may include PAs (e.g., each of the circuits 132 may include a respective power amplifier). On the other hand, if the power combiner arrangement 100 is used to divide a single input signal into multiple outputs, then the circuits 132 may include LNAs (e.g., each of the circuits 132 may include a respective LNA). In some embodiments, each of the circuits 132 may include both a power amplifier and an LNA, so that the power combiner arrangement 100 coupled to the die 102 may be configured to operate either to combine multiple input signals into a single output or to divide a single input signal into multiple outputs, as needed. In some such embodiments, an electronic assembly 130 may include a switch configured to select whether the power combiner arrangement 100 is to operate to combine multiple input signals into a single output or to operate to divide a single input signal into multiple outputs. In other embodiments, an electronic assembly 130 may include separate power combiner arrangements 100 for combining multiple input signals into a single output and dividing a single input signal into multiple outputs. For example, FIG. 3 provides a side, cross-sectional view of an electronic assembly 130 with two three-dimensional power combiner arrangements 100, labeled as a first power combiner arrangement 100-1 and a second power combiner arrangement 100-2. In some embodiments, the first power combiner arrangement 100-1 may be configured to combine multiple input signals into a single output, while the second power combiner arrangement 100-2 may be configured to divide a single input signal into multiple outputs. Although not specifically shown in the present drawings, other such pairs of first and second power combiner arrangements 100 may be included in the electronic assembly 130. In other embodiments, at least some of the multiple power combiner arrangements 100 of the electronic assembly 130 may be configured to both, combine multiple input signals into a single output or divide a single input signal into multiple outputs, in different modes of their operation. Thus, in some embodiments, each of the first power combiner arrangement 100-1 and the second power combiner arrangement 100-2 may be configured to either combine multiple input signals into a single output or to divide a single input signal into multiple outputs, as needed.

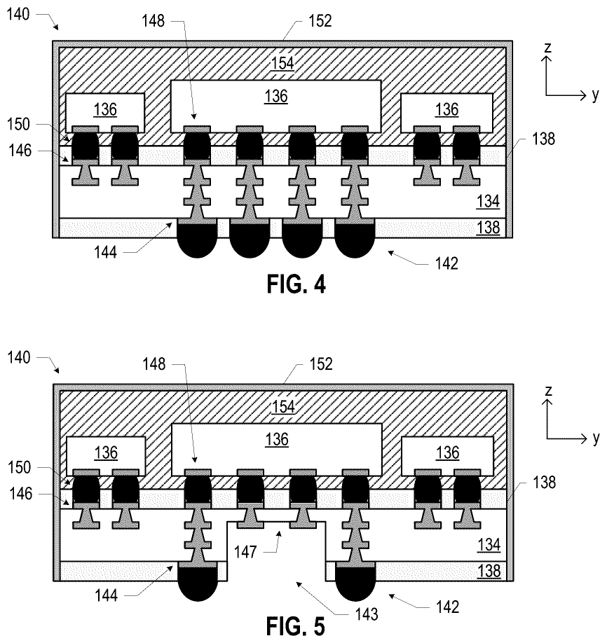

The power combiner arrangement 100 and the electronic assembly 130 may be included in any suitable IC package. For example, FIG. 4 illustrates an example IC package 140 that may include a power combiner arrangement 100. The IC package 140 may include a package substrate 134 to which one or more components 136 may be coupled by first-level interconnects 150. In particular, conductive contacts 146 at one face of the package substrate 134 may be coupled to conductive contacts 148 at faces of the components 136 by first-level interconnects 150. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). The first-level interconnects 150 illustrated in FIG. 4 are solder bumps, but any suitable first-level interconnects 150 may be used. A solder resist 138 may be disposed around the conductive contacts 146. The package substrate 134 may include a dielectric material, and may have conductive pathways (e.g., including conductive vias and lines) extending through the dielectric material between the faces, or between different locations on each face. In some embodiments, the package substrate 134 may have a thickness less than 1 millimeter (e.g., between 0.1 millimeters and 0.5 millimeters). Conductive contacts 144 may be disposed at the other face of the package substrate 134, and second-level interconnects 142 may couple these conductive contacts 144 to an antenna substrate (not shown) coupled to a power combiner arrangement 100. The second-level interconnects 142 illustrated in FIG. 4 are solder balls (e.g., for a ball grid array arrangement), but any suitable second-level interconnects 142 may be used (e.g., pins in a pin grid array arrangement or lands in a land grid array arrangement). A solder resist 138 may be disposed around the conductive contacts 144. In some embodiments, a mold material 154 may be disposed around the components 136 (e.g., between the components 136 and the package substrate 134 as an underfill material). In some embodiments, a thickness of the mold material may be less than 1 millimeter. Example materials that may be used for the mold material 154 include epoxy mold materials, as suitable. In some embodiments, a conformal shield 152 may be disposed around the components 136 and the package substrate 134 to provide electromagnetic shielding for the IC package 140.

The components 136 may include any suitable IC components that may include a three-dimensional power combiner arrangement 100, possibly as a part of an electronic assembly 200. In some embodiments, one or more of the components 136 may include a die. For example, one or more of the components 136 may be a RF communication die such as the die 102, coupled to one or more power combiner arrangements 100, as described with reference to an electronic assembly 200. In various embodiments, the die 102 and the one or more power combiner arrangements 100 may be arranged in various manners with respect to one another and the package substrate 134. For example, in some embodiments, any of the components 136 may include a die 102 and a power combiner arrangement 100 arranged so that the die 102 is closer to the package substrate 134 than the power combiner arrangement 100 (e.g., the die 102 may be coupled between the power combiner arrangement 100 and the package substrate 134). However, in other embodiments, any of the components 136 may include a die 102 and a power combiner arrangement 100 arranged so that the power combiner arrangement 100 is closer to the package substrate 134 than the die 102 (e.g., the power combiner arrangement 100 may be coupled between the die 102 and the package substrate 134). In some embodiments, one or more of the components 136 may include a resistor, capacitor (e.g., decoupling capacitors), inductor, DC-DC converter circuitry, or other circuit elements. In some embodiments, the IC package 140 may be a system-in-package (SiP). In some embodiments, the IC package 140 may be a flip chip (FC) chip scale package (CSP). In some embodiments, one or more of the components 136 may include a memory device programmed with instructions to execute beam forming, scanning, and/or codebook functions.

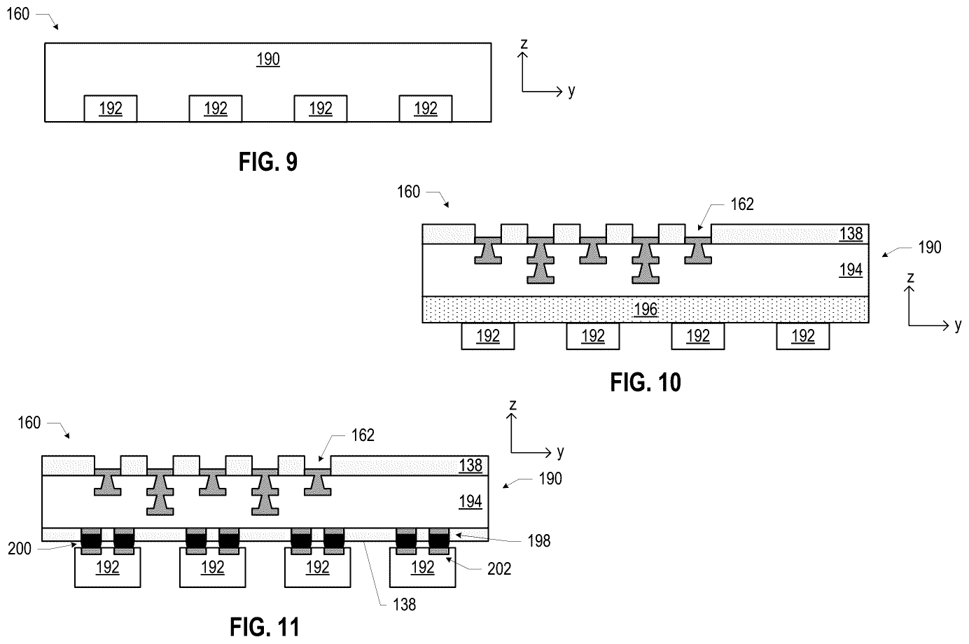

In some embodiments, a package substrate 134 of an IC package 140 in a power combiner arrangement 100 may include one or more recesses. For example, FIG. 5 illustrates an IC package 140 like the IC package 140 of FIG. 4, but in which the package substrate 134 includes a recess 143. A bottom surface 147 of the recess 143 may be provided by solid material of the package substrate 134. A recess 143 may be formed in a package substrate 134 in any suitable manner (e.g., via three-dimensional printing, laser cutting or drilling the recess 143 into an existing package substrate, etc.). One or more antenna units and/or antenna substrates may be positioned over or in a recess 143. A single recess 143 is shown in FIG. 5 for ease of illustration, but any of the IC packages 140 disclosed herein may include multiple recesses 143 in their package substrates 134. For example, a single IC package 140 may include a package substrate 134 with multiple different recesses 143 over which corresponding different antenna substrates may be mounted. In another example, a single IC package 140 may include a package substrate 134 with multiple different recesses 143 and a single antenna substrate having multiple different sets of one or more antenna units may be mounted to the IC package 140 so that different sets of one or more antenna units is mounted over different ones of the recesses 143. Examples of antenna substrates and antenna units are discussed below with reference to FIGS. 9-13.

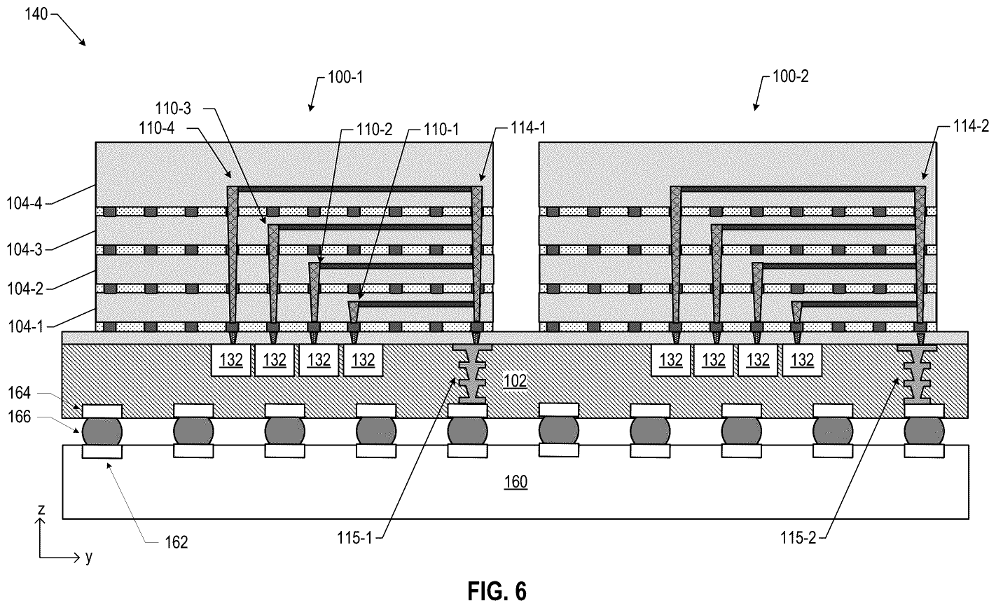

FIG. 6 illustrates yet another example IC package 140 that may include a power combiner arrangement 100. FIG. 6 illustrates first and second power combiner arrangements 100-1 and 100-2 as described with reference to FIG. 3, further illustrating that an antenna substrate 160 may be coupled to the die 102 so that the die 102 is between the power combiner arrangements 100 and the antenna substrate 160. In such embodiments, conductive pathways 115 (shown in FIG. 6 as first and second conductive pathways 115-1, 115-2) may extend through the die 102 to couple the conductive pathways 114 of the power combiner arrangements 100 to respective antenna units within the antenna substrate 160 (individual antenna units not shown in FIG. 6). As shown in FIG. 6, conductive contacts 162 at one face of the antenna substrate 160 may be coupled to conductive contacts 164 at one face of the die 102 (e.g., a face that is opposite the face to which the power combiner arrangements 100 are coupled) by interconnects 166. The first conductive pathway 115-1 may couple the conductive pathway 114-1 of the first power combiner arrangement 100-1 to one of the conductive contacts 164, while the second conductive pathway 115-2 may couple the conductive pathway 114-2 of the second power combiner arrangement 100-2 to another one of the conductive contacts 164. In some embodiments, the antenna substrate 160 may be a PCB or a multilayer package substrate based on glass, polymer, ceramic or other semiconductor packaging materials. For example, the antenna substrate 160 may be a PCB or a multilayer package substrate that includes a core including glass, e.g., a core including a glass layer, where the glass layer may be bulk glass or a solid volume of glass, as opposed to, e.g., glass fiber reinforced polymers (i.e., in some embodiments, the glass layer does not include any glass fiber reinforced polymers).

In some embodiments, the interconnects 166 may be first-level interconnects, e.g., similar to the first-level interconnects 150, described above. In other embodiments, the interconnects 166 may be second-level interconnects, e.g., similar to the second-level interconnects 142, described above. Conductive contacts 162, 164 may be similar to any other conductive contacts described herein, e.g., similar to the conductive contacts 144, 146, or 148, described above.

Although not specifically shown in FIG. 6, in some embodiments, a mold material 154 may be provided between and/or around the power combiner arrangements 100 and/or the die 102, similar to the mold material 154 shown in FIGS. 4 and 5. Furthermore, although not specifically shown in FIG. 6, a conformal shield 152 may be disposed around the power combiner arrangements 100 and the die 102 to provide electromagnetic shielding for the IC package 140 of FIG. 6, similar to the conformal shield 152 shown in FIGS. 4 and 5. Still further, although not specifically shown in FIG. 6, a solder resist 138 may be disposed around the conductive contacts 162 and 164, similar to the solder resist 138 shown in FIGS. 4 and 5.

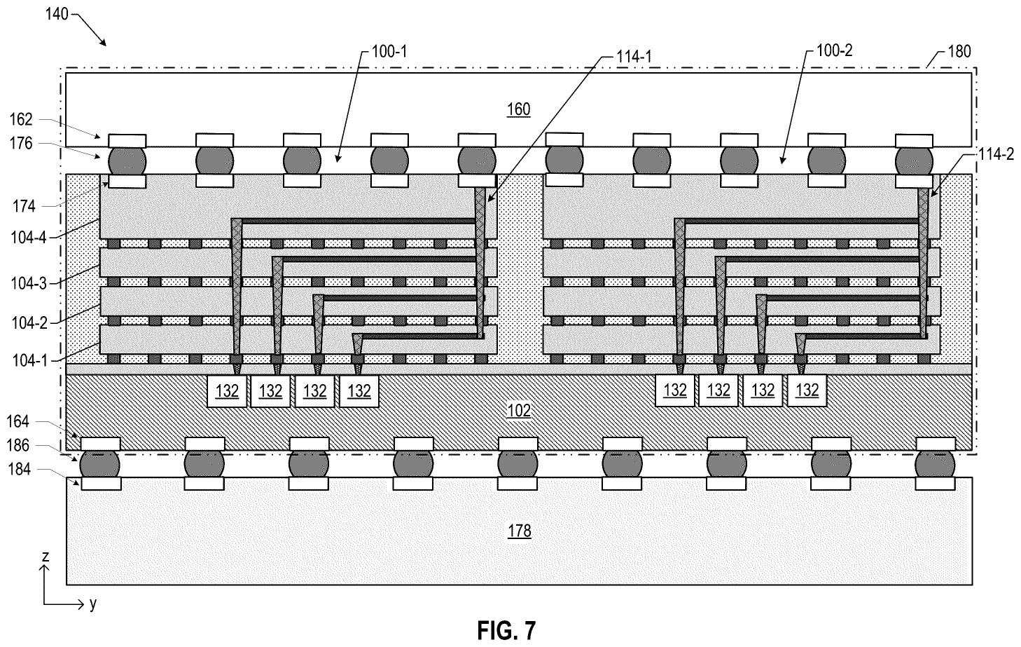

FIG. 7 illustrates yet another example IC package 140 that may include a power combiner arrangement 100. FIG. 7 illustrates first and second power combiner arrangements 100-1 and 100-2 as described with reference to FIG. 3 and FIG. 6, further illustrating that an antenna substrate 160 may be coupled (e.g., directly coupled) to the power combiner arrangements 100 so that the power combiner arrangements 100 are between the die 102 and the antenna substrate 160. In such embodiments, the conductive pathways 114 of the power combiner arrangements 100 may be coupled to respective antenna units within the antenna substrate 160 (individual antenna units not shown in FIG. 7) by means of interconnects 176. FIG. 7 illustrates that the interconnects 176 may couple the conductive contacts 162 at one face of the antenna substrate 160 and conductive contacts 172 at the top die 104 of the power combiner arrangements 100. The conductive pathway 114-1 of the first power combiner arrangement 100-1 may then be coupled to one of the conductive contacts 174, while the conductive pathway 114-2 of the second power combiner arrangement 100-2 may be coupled to another one of the conductive contacts 174. FIG. 7 further illustrates that a component 178 may be coupled to the face of the die 102 that is opposite the face to which the power combiner arrangements 100 are coupled by means of interconnects 186. In such embodiments, the interconnects 186 may couple the conductive contacts 164 at one face of the die 102 (e.g., a face that is opposite the face to which the power combiner arrangements 100 are coupled) and conductive contacts 184 at one face of the component 178. In some embodiments, the component 178 may be another die that may include additional circuitry for controlling functionality of an RF transceiver, e.g., low-frequency circuitry. In other embodiments, the component 178 may be a package substrate (e.g., a package substrate 134), a circuit board (e.g., a circuit board 194), an interposer (e.g., an interposer 1704), or any other component.

In some embodiments, the interconnects 176 or the interconnects 186 may be first-level interconnects, e.g., similar to the first-level interconnects 150, described above. In other embodiments, the interconnects 176 or the interconnects 186 may be second-level interconnects, e.g., similar to the second-level interconnects 142, described above. Conductive contacts 174, 184 may be similar to any other conductive contacts described herein, e.g., similar to the conductive contacts 144, 146, or 148, described above.

Although not specifically shown in FIG. 7, in some embodiments, a mold material 154 may be provided between and/or around the power combiner arrangements 100 and/or the die 102 and/or the component 178, similar to the mold material 154 shown in FIGS. 4 and 5. Furthermore, although not specifically shown in FIG. 7, a conformal shield 152 may be disposed around the power combiner arrangements 100, the die 102, and the component 178 to provide electromagnetic shielding for the IC package 140 of FIG. 7, similar to the conformal shield 152 shown in FIGS. 4 and 5. Still further, although not specifically shown in FIG. 7, a solder resist 138 may be disposed around the conductive contacts 162 and 164, similar to the solder resist 138 shown in FIGS. 4 and 5.

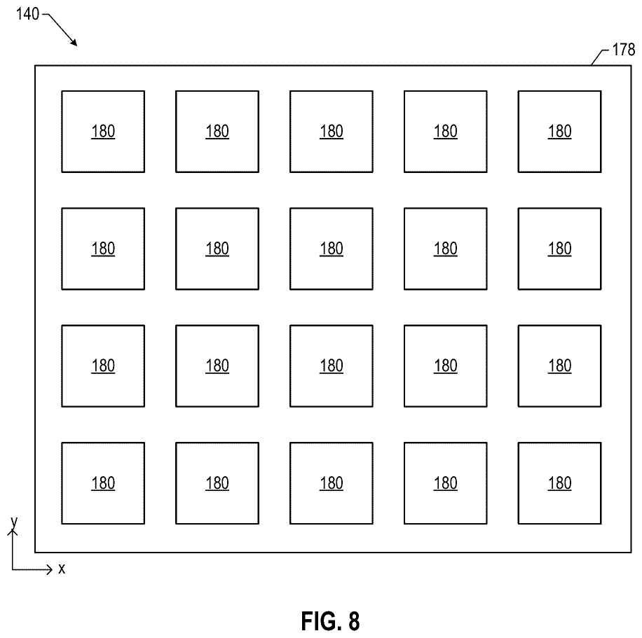

Together, the die 102, the antenna substrate 160, and the one or more power combiner arrangements 100 coupled therebetween may constitute an antenna module 180. In some embodiments, multiple such antenna modules 180 may be coupled to a single component 178, as illustrated in FIG. 8, showing a top-down view of another example IC package 140. FIG. 8 illustrates that, in some embodiments, a plurality of the antenna modules 180 may be distributed regularly on one face of the component 178; other components 178 with antenna modules 180 may have other arrangements of the antenna modules 180.

FIGS. 9-11 are side, cross-sectional views of example antenna substrates 160, in accordance with various embodiments. FIG. 9 is a generalized representation of an example antenna substrate 160 including one or more antenna units 192 coupled to an antenna support 190. In some embodiments, the antenna units 192 may be electrically coupled to the antenna support 190 by electrically conductive material pathways through the antenna support 190 that makes conductive contact with electrically conductive material of the antenna units 192, while in other embodiments, the antenna units 192 may be mechanically coupled to the antenna support 190 but may not be in contact with an electrically conductive material pathway through the antenna support 190. In some embodiments, at least a portion of the antenna support 190 may be fabricated using advanced PCB, packaging, or process technology, and may include between, for example, two and eight PCB layers. Although a particular number of antenna units 192 is depicted in FIG. 9 (and others of the accompanying drawings), this is simply illustrative, and an antenna substrate 160 may include fewer or more antenna units 192. For example, an antenna substrate 160 may include four antenna units 192 (e.g., arranged in a linear array), eight antenna units 192 (e.g., arranged in one linear array, or two or more linear arrays), sixteen antenna units 192 (e.g., arranged in a 4×4 array), or thirty-two antenna units 192 (e.g., arranged in two 4×4 arrays). In some embodiments, the antenna units 192 may be surface mount components.

In some embodiments, an IC package 140 with one or more power combiner arrangements 100 may include one or more arrays of antenna units 192 to support multiple communication bands (e.g., dual band operation or tri-band operation). For example, some of the IC packages 140 disclosed herein may support tri-band operation at 28 gigahertz, 39 gigahertz, and 60 gigahertz. Various ones of the IC packages 140 disclosed herein may support tri-band operation at 24.5 gigahertz to 29 gigahertz, 37 gigahertz to 43 gigahertz, and 57 gigahertz to 71 gigahertz. Various ones of the IC packages 140 disclosed herein may support 5G communications and 60 gigahertz communications. Various ones of the IC packages 140 disclosed herein may support 28 gigahertz and 39 gigahertz communications. Various ones of the IC packages 140 disclosed herein may support operation in bands above about 100 gigahertz, above about 200 gigahertz, or above about 300 gigahertz. Various of the IC packages 140 disclosed herein may support millimeter wave or THz wave communications. Various of the IC packages 140 disclosed herein may support high band frequencies and low band frequencies.

In some embodiments, an antenna substrate 160 may include an antenna unit 192 coupled to an antenna support 190 by an adhesive. FIG. 10 illustrates an antenna substrate 160 in which the antenna support 190 includes a circuit board 194 (e.g., including between two and eight PCB layers), a solder resist 138 and conductive contacts 162 at one face of the circuit board 194, and an adhesive 196 at the opposite face of the circuit board 194.

The circuit board 194 may include traces, vias, and other structures, as known in the art, formed of an electrically conductive material (e.g., a metal, such as copper). The conductive structures in the circuit board 194 may be electrically insulated from each other by a dielectric material. Any suitable dielectric material may be used (e.g., a laminate material). In some embodiments, the dielectric material may be an organic dielectric material, a fire retardant grade 4 material (FR-4), bismaleimide triazine (BT) resin, polyimide materials, glass reinforced epoxy matrix materials, or low-k and ultra low-k dielectric (e.g., carbon-doped dielectrics, fluorine-doped dielectrics, porous dielectrics, and organic polymeric dielectrics).

In the embodiment of FIG. 10, the antenna units 192 may be adhered to the adhesive 196. The adhesive 196 may be electrically non-conductive, and thus the antenna units 192 may not be electrically coupled to the circuit board 194 by an electrically conductive material pathway. In some embodiments, the adhesive 196 may be an epoxy. The thickness of the adhesive 196 may control the distance between the antenna units 192 and the proximate face of the circuit board 194. When the antenna substrate 160 of FIG. 10 (and others of the accompanying drawings) is used in an IC package 140 with at least one power combiner arrangement 100, a die 102 may be coupled to some of the conductive contacts 162 (e.g., as shown in FIG. 6) or one or more power combiner arrangements 100 may be coupled to some of the conductive contacts 162 (e.g., as shown in FIG. 7). In some embodiments, a thickness of the circuit board 194 of FIG. 10 may be less than 1 millimeter (e.g., between 0.35 millimeters and 0.5 millimeters). In some embodiments, a thickness of an antenna unit 192 may be less than 1 millimeter (e.g., between 0.4 millimeters and 0.7 millimeters).

In some embodiments, an antenna substrate 160 may include an antenna unit 192 coupled to an antenna support 190 by solder. FIG. 11 illustrates an antenna substrate 160 in which the antenna support 190 includes a circuit board 194 (e.g., including between two and eight PCB layers), a solder resist 138 and conductive contacts 162 at one face of the circuit board 194, and a solder resist 138 and conductive contacts 198 at the opposite face of the circuit board 194. The antenna units 192 may be secured to the circuit board 194 by solder 200 (or other second-level interconnects) between conductive contacts 202 of the antenna units 192 and the conductive contacts 198. In some embodiments, the conductive contacts 198/solder 200/conductive contacts 202 may provide an electrically conductive material pathway through which signals may be transmitted to or from the antenna units 192. In other embodiments, the conductive contacts 198/solder 200/conductive contacts 202 may be used only for mechanical coupling between the antenna units 192 and the antenna support 190. The height of the solder 200 (or other interconnects) may control the distance between the antenna units 192 and the proximate face of the circuit board 194.

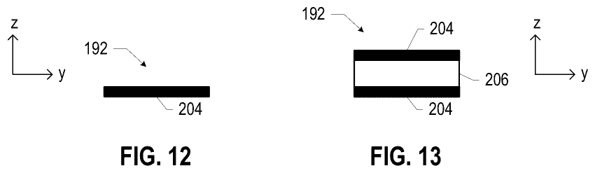

Any suitable antenna structures may provide the antenna units 192 of an IC package 140. In some embodiments, an antenna unit 192 may include one, two, three, or more antenna layers. For example, FIGS. 12 and 13 are side, cross-sectional views of example antenna units 192, in accordance with various embodiments. In FIG. 12, the antenna unit 192 includes one antenna patch 204, while in FIG. 13, the antenna unit 192 includes two antenna patches 204 spaced apart by an intervening structure 206.

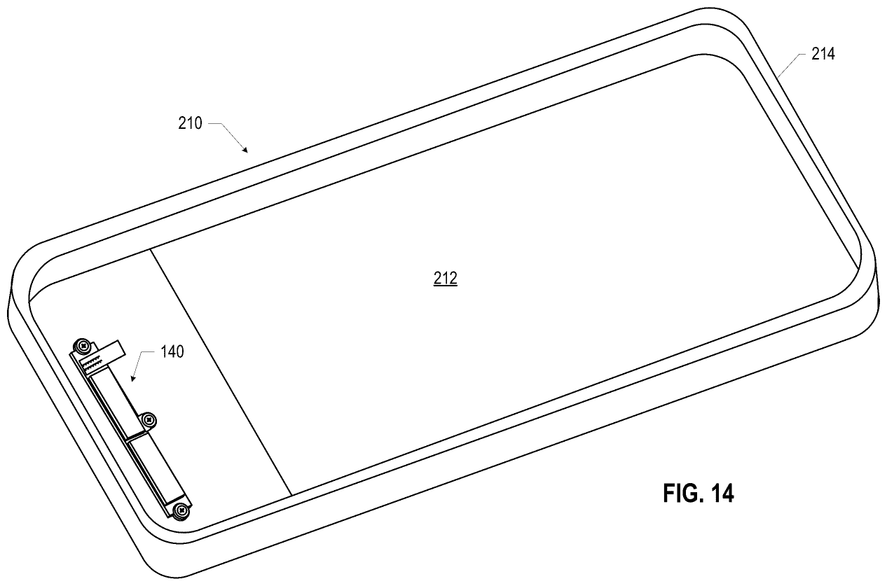

The power combiner arrangements 100 disclosed herein may be included in any suitable communication device (e.g., a computing device with wireless communication capability, a wearable device with wireless communication circuitry, etc.). For example, FIG. 14 is a perspective view of a handheld communication device 210 including an IC package 140 with one or more power combiner arrangements 100, in accordance with various embodiments. In particular, FIG. 14 depicts that the power combiner arrangement 100 (and associated antenna substrate fixtures) may be coupled to a chassis 212 of the handheld communication device 210. A metal or plastic housing 214 may provide the “sides” of the communication device 210. In some embodiments, the handheld communication device 210 may be a smart phone.

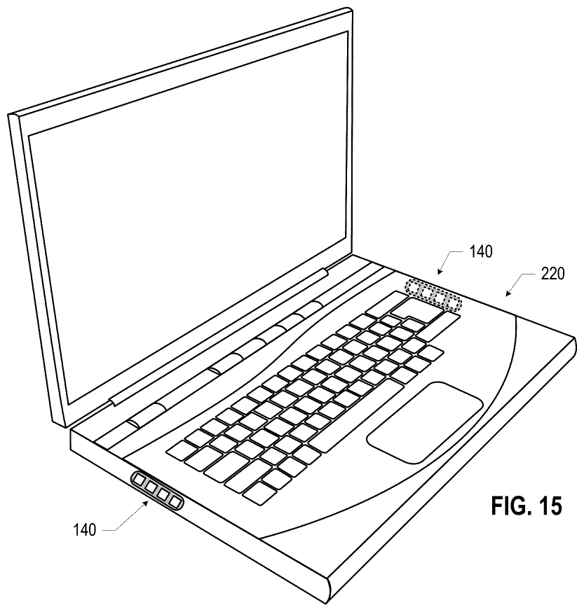

FIG. 15 is a perspective view of a laptop communication device 220 including multiple IC package 140, each including one or more power combiner arrangements 100, in accordance with various embodiments. In particular, FIG. 15 depicts an IC package 140 having four antenna units 192, coupled to one or more power combiner arrangements 100 in accordance with any of the embodiments described herein, at either side of the keyboard of a laptop communication device 220. The antenna units 192 may occupy an area on the outside housing of the laptop communication device 220 that is approximately equal to or less than the area required for two adjacent Universal Serial Bus (USB) connectors (i.e., approximately 5 millimeters (height) by 22 millimeters (width) by 2.2 millimeters (depth)).

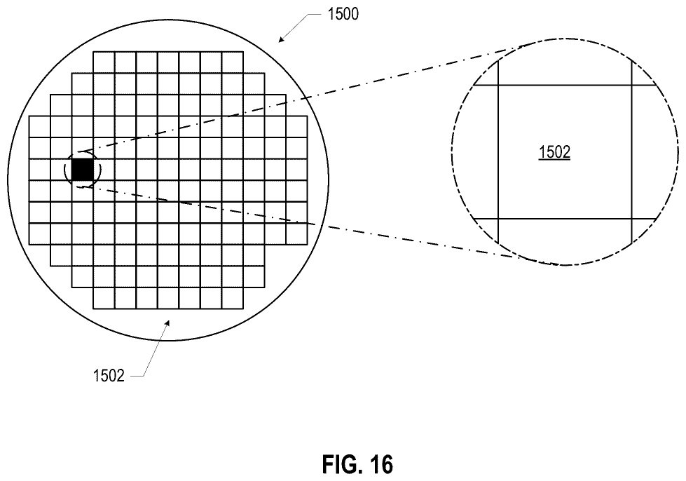

The three-dimensional power combiner arrangements 100 disclosed herein may include, or be included in, any suitable electronic component. FIGS. 16-20 illustrate various examples of apparatuses that may include, or be included in, any of the three-dimensional power combiner arrangements 100 disclosed herein.

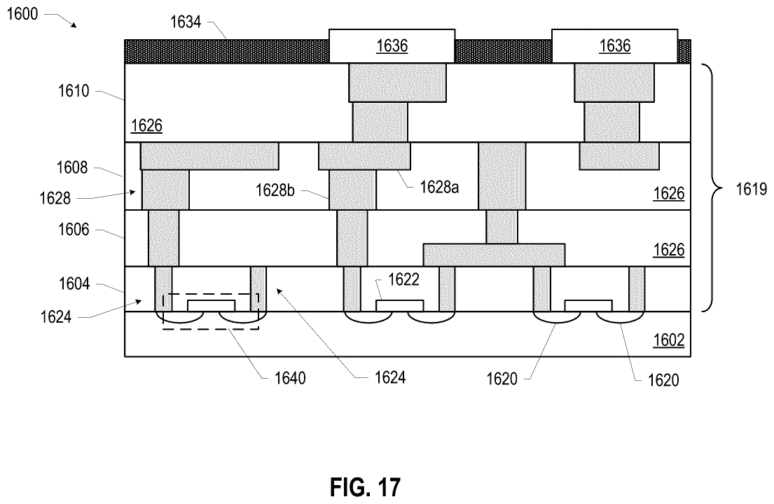

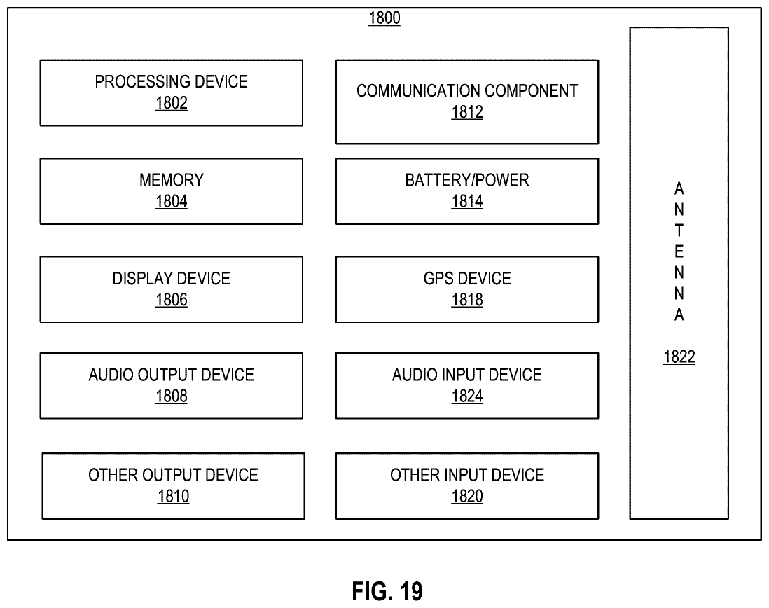

FIG. 16 is a top view of a wafer 1500 and dies 1502 that may be included in any of the power combiner arrangements 100 disclosed herein. For example, a die 1502 may be any of the dies 104 or may be included in an electronic assembly 130 (e.g., as a die 102) or may be included in an IC package 140 (e.g., as a component 136) or in an antenna unit 192. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 17, discussed below) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 19) or other logic that is configured to store information in the memory devices or execute instructions stored in the memory array.

FIG. 17 is a side, cross-sectional view of an IC device 1600 that may be included in any of the power combiner arrangements 100 disclosed herein. For example, an IC device 1600 may be included in an IC package 140 (e.g., as a component 136 or as a die 102). The IC device 1600 may be formed on a substrate 1602 (e.g., the wafer 1500 of FIG. 16) and may be included in a die (e.g., the die 1502 of FIG. 16). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 16) or a wafer (e.g., the wafer 1500 of FIG. 16).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 17 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 17 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 17). Although a particular number of interconnect layers 1606-1610 is depicted in FIG. 17, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 17. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 17. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 17, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

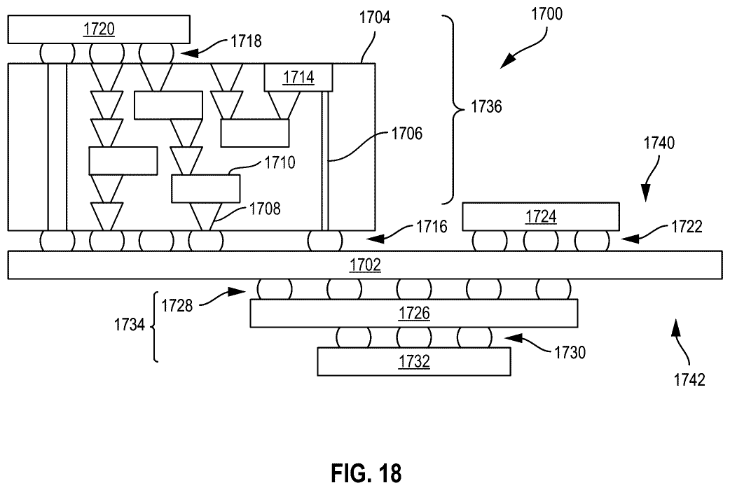

FIG. 18 is a side, cross-sectional view of an IC device assembly 1700 that may include one or more of the power combiner arrangements 100 disclosed herein. In particular, any suitable ones of the power combiner arrangements 100 disclosed herein may take the place of any of the components of the IC device assembly 1700 (e.g., a power combiner arrangement 100 may take the place of any of the IC packages of the IC device assembly 1700).

The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 18 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 18), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 18, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 16), an IC device (e.g., the IC device 1600 of FIG. 17), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 18, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through-silicon vias (TSVs) 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, PAs, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 18 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 19 is a block diagram of an example communication device 1800 that may include one or more power combiner arrangements 100 in accordance with any of the embodiments disclosed herein. The handheld communication device 210 (FIG. 14), and the laptop communication device 220 (FIG. 15) may be examples of the communication device 1800. Any suitable ones of the components of the communication device 1800 may include one or more of the IC packages 1650, IC devices 1600, or dies 1502 disclosed herein. A number of components are illustrated in FIG. 19 as included in the communication device 1800, but any one or more of these components may be omitted or duplicated, as suitable for the application. In some embodiments, some or all of the components included in the communication device 1800 may be attached to one or more motherboards. In some embodiments, some or all of these components are fabricated onto a single system-on-a-chip (SoC) die.

Additionally, in various embodiments, the communication device 1800 may not include one or more of the components illustrated in FIG. 19, but the communication device 1800 may include interface circuitry for coupling to the one or more components. For example, the communication device 1800 may not include a display device 1806, but may include display device interface circuitry (e.g., a connector and driver circuitry) to which a display device 1806 may be coupled. In another set of examples, the communication device 1800 may not include an audio input device 1824 or an audio output device 1808, but may include audio input or output device interface circuitry (e.g., connectors and supporting circuitry) to which an audio input device 1824 or audio output device 1808 may be coupled.

The communication device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The communication device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the communication device 1800 may include a communication module 1812 (e.g., one or more communication modules). For example, the communication module 1812 may be configured for managing wireless communications for the transfer of data to and from the communication device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not. The communication module 1812 may be, or may include, any of the power combiner arrangements 100 disclosed herein.

The communication module 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication module 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication module 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication module 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication module 1812 may operate in accordance with other wireless protocols in other embodiments. The communication device 1800 may include an antenna 1822 to facilitate wireless communications and/or to receive other wireless communications (such as AM or FM radio transmissions).

In some embodiments, the communication module 1812 may manage wired communications, such as electrical, optical, or any other suitable communication protocols (e.g., the Ethernet). As noted above, the communication module 1812 may include multiple communication modules. For instance, a first communication module 1812 may be dedicated to shorter-range wireless communications such as Wi-Fi or Bluetooth, and a second communication module 1812 may be dedicated to longer-range wireless communications such as global positioning system (GPS), EDGE, GPRS, CDMA, WiMAX, LTE, EV-DO, or others. In some embodiments, a first communication module 1812 may be dedicated to wireless communications, and a second communication module 1812 may be dedicated to wired communications. In some embodiments, the communication module 1812 may include a power combiner arrangement 100 that supports millimeter wave communication.

The communication device 1800 may include battery/power circuitry 1814. The battery/power circuitry 1814 may include one or more energy storage devices (e.g., batteries or capacitors) and/or circuitry for coupling components of the communication device 1800 to an energy source separate from the communication device 1800 (e.g., AC line power).

The communication device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The communication device 1800 may include an audio output device 1808 (or corresponding interface circuitry, as discussed above). The audio output device 1808 may include any device that generates an audible indicator, such as speakers, headsets, or earbuds.

The communication device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The communication device 1800 may include a GPS device 1818 (or corresponding interface circuitry, as discussed above). The GPS device 1818 may be in communication with a satellite-based system and may receive a location of the communication device 1800, as known in the art.

The communication device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The communication device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The communication device 1800 may have any desired form factor, such as a handheld or mobile communication device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop communication device, a server or other networked computing component, a printer, a scanner, a monitor, a set-top box, an entertainment control unit, a vehicle control unit, a digital camera, a digital video recorder, or a wearable communication device. In some embodiments, the communication device 1800 may be any other electronic device that processes data.

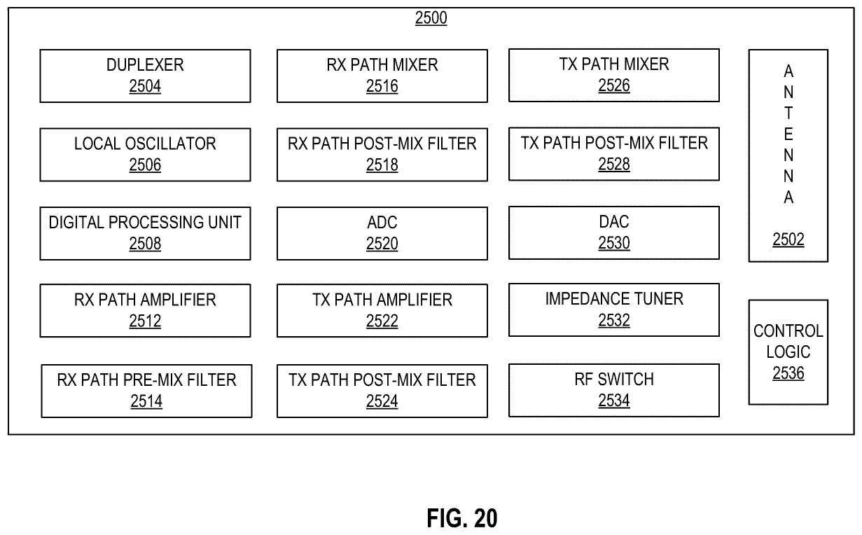

FIG. 20 is a block diagram of an example RF device 2500 that may include one or more power combiner arrangements 100 in accordance with any of the embodiments disclosed herein. For example, any suitable ones of the components of the RF device 2500 may include, or may be included in an electronic assembly 130 or an IC package 140 in accordance with any of the embodiments disclosed herein. Any of the components of the RF device 2500 may include, or be included in, an IC assembly 1700 as described with reference to FIG. 18. In some embodiments, the RF device 2500 may be included within any components of the computing device 1800 as described above with reference to FIG. 19 (e.g., the communication component 1812), or may be coupled to any of the components of the electrical device 1800 (e.g., may be coupled to the memory 1804 and/or to the processing device 1802 of the electrical device 1800). In still other embodiments, the RF device 2500 may further include any of the components described above with reference to FIG. 19, such as, but not limited to, the battery/power circuitry 1814, the memory 1804, and various input and output devices as discussed above with reference to FIG. 19.

In general, the RF device 2500 may be any device or system that may support wireless transmission and/or reception of signals in the form of electromagnetic waves in the RF range of approximately 3 kiloHertz (kHz) to 300 gigaHertz (GHz) and beyond. In some embodiments, the RF device 2500 may be used for wireless communications, e.g., in a base station (BS) or a user equipment (UE) device of any suitable cellular wireless communications technology, such as GSM, WCDMA, or LTE. In a further example, the RF device 2500 may be used as, or in, a BS or a UE device of a millimeter wave wireless technology such as fifth generation (5G) wireless (e.g., high-frequency/short wavelength spectrum, with frequencies in the range between about 20 and 60 GHz, corresponding to wavelengths in the range between about 5 and 15 millimeters). In yet another example, the RF device 2500 may be used for wireless communications using Wi-Fi technology (e.g., a frequency band of 2.4 GHz, corresponding to a wavelength of about 12 cm, or a frequency band of 5.8 GHz, corresponding to a wavelength of about 5 cm). For example, the RF device 2500 may be included in a Wi-Fi-enabled device such as a desktop, a laptop, a video game console, a smart phone, a tablet, a smart TV, a digital audio player, a car, a printer, etc. In some implementations, a Wi-Fi-enabled device may be a node (e.g., a smart sensor) in a smart system configured to communicate data with other nodes. In another example, the RF device 2500 may be used for wireless communications using Bluetooth technology (e.g., a frequency band from about 2.4 to about 2.485 GHz, corresponding to a wavelength of about 12 cm). In other embodiments, the RF device 2500 may be used for transmitting and/or receiving RF signals for purposes other than communication (e.g., in an automotive radar system, or in medical applications such as magnetic resonance imaging (MRI)).

In various embodiments, the RF device 2500 may be included in frequency-division duplex (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 20 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In various embodiments, the RF device 2500 may not include one or more of the components illustrated in FIG. 20, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 20, the RF device 2500 may include an antenna 2502, a duplexer 2504, a local oscillator 2506, and a digital processing unit 2508. As also shown in FIG. 20, the RF device 2500 may include an RX path that may include an RX path amplifier 2512 (which may be coupled to any of the power combiner arrangements 100 disclosed herein), an RX path pre-mix filter 2514, a RX path mixer 2516, an RX path post-mix filter 2518, and an analog-to-digital converter (ADC) 2520. As further shown in FIG. 20, the RF device 2500 may include a TX path that may include a TX path amplifier 2522 (which may be coupled to any of the power combiner arrangements 100 disclosed herein), a TX path post-mix filter 2524, a TX path mixer 2526, a TX path pre-mix filter 2528, and a digital-to-analog converter (DAC) 2530. Still further, the RF device 2500 may further include an impedance tuner 2532, an RF switch 2534, and control logic 2536. In various embodiments, the RF device 2500 may include multiple instances of any of the components shown in FIG. 20. In some embodiments, the RX path amplifier 2512, the TX path amplifier 2522, the duplexer 2504, and the RF switch 2534 may be considered to form, or be a part of, an RF front-end (FE) of the RF device 2500. In some embodiments, the RX path amplifier 2512, the TX path amplifier 2522, the duplexer 2504, and the RF switch 2534 may be considered to form, or be a part of, an RF FE of the RF device 2500. In some embodiments, the RX path mixer 2516 and the TX path mixer 2526 (possibly with their associated pre-mix and post-mix filters shown in FIG. 20) may be considered to form, or be a part of, an RF transceiver of the RF device 2500 (or of an RF receiver or an RF transmitter if only RX path or TX path components, respectively, are included in the RF device 2500). In some embodiments, the RF device 2500 may further include one or more control logic elements/circuits, shown in FIG. 20 as control logic 2536 (providing, for example, an RF FE control interface). The control logic 2536 may be used to enhance control of complex RF system environment, support implementation of envelope tracking techniques, reduce dissipated power, etc.

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, e.g., non-overlapping and non-continuous, bands of frequencies, e.g., in bands having a separation of, e.g., 20 MHz from one another. If the RF device 2500 is a TDD transceiver, the antenna 2502 may be configured for sequential reception and transmission of communication signals in bands of frequencies that may be the same or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (e.g., a plurality of antennas each configured to receive and/or transmit signals in a specific band of frequencies). In various embodiments, the antenna 2502 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals that may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 1802 of FIG. 19, descriptions of which are provided above. The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 20, in some embodiments, the RF device 2500 may further include a memory device (e.g., the memory device 1804 described above with reference to FIG. 19) configured to cooperate with the digital processing unit 2508.

Turning to the details of the RX path that may be included in the RF device 2500, the RX path amplifier 2512 may include an LNA. An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be a harmonic or band-pass (e.g., low-pass) filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the RX path mixer (e.g., downconverter) 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-intermediate frequency (IF) receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an IF. IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 20, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset, in phase, from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the RX path post-mix filter 2518.

The ADC 2520 may be configured to convert the mixed RX signals from the RX path mixer 2516 from the analog to the digital domain. The ADC 2520 may be a quadrature ADC that, similar to the RX path mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a band-pass (e.g., low-pass) filter (or a pair of band-pass, e.g., low-pass, filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the RX path mixer 2516 in the RX path and the TX path mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

As noted above, the TX path amplifier 2522 may be a power amplifier, configured to amplify the upconverted RF signal before providing it to the antenna 2502 for transmission.

In various embodiments, any of the RX path pre-mix filter 2514, the RX path post-mix filter 2518, the TX path post-mix filter 2524, and the TX path pre-mix filter 2528 may be implemented as RF filters. In some embodiments, each of such RF filters may include one or more resonators (e.g., AWRs, film bulk acoustic resonators (FBARs), Lamb wave resonators, and/or contour-wave resonators), arranged in any suitable manner (e.g., in a ladder configuration). In some embodiments, an RF filter may be implemented as a plurality of RF filters, or a filter bank. A filter bank may include a plurality of RF resonators that may be coupled to a switch (e. g., the RF switch 2534) configured to selectively switch any one of the plurality of RF resonators on and off (e.g., activate any one of the plurality of RF resonators), in order to achieve desired filtering characteristics of the filter bank (e.g., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g., antenna's impedance changes depending on, e.g., if the antenna is held in a hand, placed on a car roof, etc.

As described above, the RF switch 2534 may be a device configured to route high-frequency signals through transmission paths in order to selectively switch between a plurality of instances of any one of the components shown in FIG. 20 (e.g., to achieve desired behavior and characteristics of the RF device 2500). In some embodiments, an RF switch 2534 may be used to switch between different antennas 2502. In other embodiments, an RF switch may be used to switch between a plurality of RF resonators (e.g., by selectively switching RF resonators on and off) of any of the filters included in the RF device 2500. Typically, an RF system may include a plurality of such RF switches.

The RF device 2500 provides a simplified version and, in further embodiments, other components not specifically shown in FIG. 20 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may include a suitable phase-lock loop (PLL), configured to receive a reference clock signal and use it to generate a different clock signal that may then be used for timing the operation of the ADC 2520, the DAC 2530, and/or that may also be used by the local oscillator 2506 to generate the local oscillator signals to be used in the RX path or the TX path.

The following paragraphs provide examples of various ones of the embodiments disclosed herein.

Example 1 provides an electronic assembly that includes a first die, including a first transmission line; a second die, including a second transmission line, where each of the first die and the second die includes a first face and an opposing second face, the first face of the second die is coupled to the second face of the first die (i.e., the second die is stacked above the first die), and each of the first transmission line and the second transmission line has a first end and an opposing second end; a first electrically conductive pathway between (i.e., electrically connecting, e.g., directly connecting) the first end of the first transmission line and a first connection point at the first face of the first die; a second electrically conductive pathway between (i.e., electrically connecting, e.g., directly connecting) the first end of the second transmission line and a second connection point at the first face of the first die; and a third electrically conductive pathway between (i.e., electrically connecting, e.g., directly connecting) the second end of the first transmission line and the second end of the second transmission line.

Example 2 provides the electronic assembly according to example 1, where the first die has a thickness below about 40 microns, e.g., between about 2 microns and 40 microns, between about 5 microns and 30 microns, or between about 10 microns and 30 microns. Other dies implementing other branches of the three-dimensional power combiner may have similar thicknesses.

Example 3 provides the electronic assembly according to examples 1 or 2, where the first conductive pathway includes a conductive via between (i.e., electrically connecting, e.g., directly connecting) the first end of the first transmission line and the first connection point at the first face of the first die.

Example 4 provides the electronic assembly according to any one of the preceding examples, where the second conductive pathway includes a direct bonding interconnect between (i.e., electrically connecting, e.g., directly connecting) the first die and the second die.

Example 5 provides the electronic assembly according to example 4, where the second conductive pathway further includes a conductive via in the first die, between (i.e., electrically connecting, e.g., directly connecting) the direct bonding interconnect at the second face of the first die and the second connection point at the first face of the first die.

Example 6 provides the electronic assembly according to examples 4 or 5, where the second conductive pathway further includes a conductive via in the second die, between (i.e., electrically connecting, e.g., directly connecting) the first end of the second transmission line and the direct bonding interconnect at the first face of the second die.

Example 7 provides the electronic assembly according to any one of the preceding examples, where a distance between the first die and the second die is below about 10 microns, e.g., below about 5 microns or below about 2 microns, e.g., between about 0.5 microns and 2 microns.

Example 8 provides the electronic assembly according to any one of the preceding examples, where no solder is present at an interface between the second face of the first die and the first face of the second die.

Example 9 provides the electronic assembly according to any one of the preceding examples, where the second transmission line is vertically aligned with the first transmission line (e.g., projections of the first and second transmission lines onto a plane parallel to the first or the second face of the first die may be overlapping).

Example 10 provides the electronic assembly according to any one of the preceding examples, further including a base die having a first face and an opposing second face, where the second face of the base die is coupled to the first face of the first die, the base die includes a first amplifier coupled (e.g., directly electrically connected) to the first connection point at the first face of the first die, and the base die further includes a second amplifier coupled (e.g., directly electrically connected) to the second connection point at the first face of the first die.

Example 11 provides the electronic assembly according to example 10, where: the base die further includes a third amplifier coupled (e.g., directly electrically connected) to the first connection point (e.g., 112-1) at the first face of the first die, and one of the first amplifier and the third amplifier is a power amplifier and another one of the first amplifier and the third amplifier is an LNA.

Example 12 provides the electronic assembly according to examples 10 or 11, further including an antenna module and a fourth electrically conductive pathway, where: the antenna module is coupled to the first face of the base die and includes an antenna unit, the fourth electrically conductive pathway is between the first face of the base die and the second face of the base die, one end of the fourth conductive pathway is coupled to the antenna unit, and another end of the fourth conductive pathway is coupled to the third conductive pathway.

Example 13 provides the electronic assembly according to examples 10 or 11, further including an antenna module and a fourth electrically conductive pathway, where: the antenna module is closer to the second face of the second die than the first face of the second die and includes an antenna unit, one end of the fourth conductive pathway is coupled to the antenna unit, and another end of the fourth conductive pathway is coupled to the third conductive pathway.

Example 14 provides an electronic assembly that includes a plurality of dies stacked above one another, and a three-dimensional power combiner, including a first branch in a first die of the plurality of dies, and further including a second branch in a second die of the plurality of dies.

Example 15 provides the electronic assembly according to example 14, further including a direct bonding interface between the first die and the second die.

Example 16 provides the electronic assembly according to example 15, where each of the first branch and the second branch includes a first end and a second end, the electronic assembly further includes a direct bonding interconnect that connects the first end of the first branch with the first end of the second branch, the second end of the first branch is connected to a first input or output terminal of the electronic assembly, and the second end of the second branch is connected to a second input or output terminal of the electronic assembly.

Example 17 provides the electronic assembly according to example 16, where the direct bonding interconnect is connected to a third input or output terminal of the electronic assembly, the first input or output terminal and the second input or output terminal are closer to a first face of the first die than to a second face of the first die, the second face of the first die being opposite the first face of the first die, and the third input or output terminal is closer to the second face of the first die.

Example 18 provides the electronic assembly according to any one of examples 14-17, where the first branch includes a first transmission line parallel to an interface between the first die and the second die, and the second branch includes a second transmission line parallel to the interface.

Example 19 provides a system that includes a circuit board; and an electronic assembly, communicatively coupled to the circuit board, where the electronic assembly includes a face of a first die direct bonded to a face of a second die, and a power combiner having a first branch in the first die and a second branch in the second die.

Example 20 provides the system of example 19, where the system further includes a display communicatively coupled to the circuit board.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An electronic assembly, comprising:
a first die, comprising a first transmission line;
a second die, comprising a second transmission line, wherein each of the first die and the second die includes a first face and an opposing second face, the first face of the second die is coupled to the second face of the first die, and each of the first transmission line and the second transmission line has a first end and an opposing second end;
a first conductive pathway between the first end of the first transmission line and a first connection point at the first face of the first die;
a second conductive pathway between the first end of the second transmission line and a second connection point at the first face of the first die; and
a third conductive pathway between the second end of the first transmission line and the second end of the second transmission line.

2. The electronic assembly according to claim 1, wherein the first die has a thickness below about 40 microns.

3. The electronic assembly according to claim 1, wherein the first conductive pathway includes a conductive via between the first end of the first transmission line and the first connection point at the first face of the first die.

4. The electronic assembly according to claim 1, wherein the second conductive pathway includes a direct bonding interconnect between the first die and the second die.

5. The electronic assembly according to claim 4, wherein the second conductive pathway further includes a conductive via in the first die, between the direct bonding interconnect at the second face of the first die and the second connection point at the first face of the first die.

6. The electronic assembly according to claim 5, wherein the second conductive pathway further includes a conductive via in the second die, between the first end of the second transmission line and the direct bonding interconnect at the first face of the second die.

7. The electronic assembly according to claim 1, wherein a distance between the first die and the second die is below about 10 microns.

8. The electronic assembly according to claim 1, wherein no solder is present at an interface between the second face of the first die and the first face of the second die.

9. The electronic assembly according to claim 1, wherein the second transmission line is vertically aligned with the first transmission line.

10. The electronic assembly according to claim 1, further comprising a base die having a first face and an opposing second face, wherein:
the second face of the base die is coupled to the first face of the first die,
the base die includes a first amplifier coupled to the first connection point at the first face of the first die, and
the base die further includes a second amplifier coupled to the second connection point at the first face of the first die.

11. The electronic assembly according to claim 10, wherein:
the base die further includes a third amplifier coupled to the first connection point at the first face of the first die, and
one of the first amplifier and the third amplifier is a power amplifier and another one of the first amplifier and the third amplifier is a low-noise amplifier.

12. The electronic assembly according to claim 10, further comprising an antenna module and a fourth conductive pathway, wherein:
the antenna module is coupled to the first face of the base die and includes an antenna unit,
the fourth conductive pathway is between the first face of the base die and the second face of the base die,
one end of the fourth conductive pathway is coupled to the antenna unit, and
another end of the fourth conductive pathway is coupled to the third conductive pathway.

13. The electronic assembly according to claim 10, further comprising an antenna module and a fourth conductive pathway, wherein:
the antenna module is closer to the second face of the second die than the first face of the second die and includes an antenna unit,
one end of the fourth conductive pathway is coupled to the antenna unit, and
another end of the fourth conductive pathway is coupled to the third conductive pathway.

14. An electronic assembly, comprising:
a plurality of dies stacked above one another; and
a three-dimensional power combiner, comprising a first branch in a first die of the plurality of dies, and further comprising a second branch in a second die of the plurality of dies.

15. The electronic assembly according to claim 14, further comprising a direct bonding interface between the first die and the second die.

16. The electronic assembly according to claim 15, wherein:
each of the first branch and the second branch includes a first end and a second end,
the electronic assembly further includes a direct bonding interconnect that connects the first end of the first branch with the first end of the second branch,
the second end of the first branch is connected to a first terminal of the electronic assembly, and
the second end of the second branch is connected to a second terminal of the electronic assembly.

17. The electronic assembly according to claim 16, wherein:
the direct bonding interconnect is connected to a third terminal of the electronic assembly,
the first terminal and the second terminal are closer to a first face of the first die than to a second face of the first die, the second face of the first die being opposite the first face of the first die, and
the third terminal is closer to the second face of the first die.

18. The electronic assembly according to claim 14, wherein:
the first branch includes a first transmission line parallel to an interface between the first die and the second die, and
the second branch includes a second transmission line parallel to the interface.

19. A system, comprising:
a circuit board; and
an electronic assembly, communicatively coupled to the circuit board, wherein the electronic assembly includes a face of a first die direct bonded to a face of a second die, and a power combiner having a first branch in the first die and a second branch in the second die.

20. The system of claim 19, wherein the system further includes a display communicatively coupled to the circuit board.
